(19) United States
(12) Patent Application Publication
(10) Pub. No.: US 2012/0210575 A1
(43) Pub. Date: Aug. 23, 2012

(54) ELECTRIC CONTACT FOR A CONNECTOR

(75) Inventor: Fabien BOURGEAS, Saint Nicolas De Macherin (FR)

(73) Assignee: RADIALL, Rosny Sous Bois (FR)

(21) Appl. No.: 13/369,915

(22) Filed: Feb. 9, 2012

(30) Foreign Application Priority Data
Feb. 22, 2011 (FR) 11 51425

(51) Int. Cl. H01R 24/00; H01R 9/22; H05K 3/36; H01R 13/02

(52) U.S. Cl. 29/830; 439/861; 439/708; 439/660

(57) ABSTRACT

An electric contact for a connector, the contact including a first end for connecting to another contact; and a second end opposite from the first end along a longitudinal axis of the contact; wherein the contact includes at least two distinct arms forming the first end and a middle portion arranged between the first and second ends and configured to enable the arms to move apart and/or towards each other, and wherein each arm is such that the two arms slope apart from each other on moving along the projection of an arm onto the plane perpendicular to the longitudinal axis of the contact.

### FIELD OF THE INVENTION

The present invention relates to an electric contact for a connector, in particular a connector that enables one electronic card to be connected to another (also referred to below as an “electronic card connector”). The invention applies in particular to base station equipment, where such equipment comprises a variety of assemblies of radiofrequency modules. Such radiofrequency modules comprise electronic cards that are suitable for performing different functions and that are connected together by connectors that differ depending on the types of signal they are to pass, in particular a high-power signal, a radiofrequency signal, or a digital signal.

### BACKGROUND OF THE INVENTION

In order to connect two electronic cards together, it is known to make use of circular or rectangular connectors that are arranged at the edge of the card and that are configured for plugging with a connector of the other card parallel to the plane in which each electronic card extends. With known connectors, the axis along which plugging takes place is imposed.

Known connectors are mounted on an electronic card and comprise a body having one or more male and/or female type contacts arranged therein, the contacts of the male type and the contacts of the female type being structurally different.

Examples of such electric contacts for a connector are described in documents U.S. Pat. No. 7,387,521, EP 1 624 533, and U.S. Pat. No. 6,461,183.

There exists a need to benefit from a contact that is simple to make and that makes it possible, when used in an electronic card connector, to have great freedom in selecting the axis along which the connector is plugged with a complementary connector in order to connect together two electronic cards of radiofrequency modules.

### OBJECT AND SUMMARY OF THE INVENTION

An object of the invention is to satisfy this need and in exemplary embodiments the invention achieves this object by an electric contact for a connector, the contact comprising:
a first end for connecting to another contact; and
a second end opposite from the first end along a longitudinal axis of the contact;

wherein the contact includes at least two distinct arms forming the first end and a middle portion arranged between the first and second ends and configured to enable said arms to move apart and/or towards each other, and wherein each arm is such that the two arms slope apart from each other on moving along the projection of an arm onto the plane perpendicular to the longitudinal axis of the contact.

Moving the arms apart or towards each other enables the contact to be used either as a contact of the male type or as a contact of the female type. The invention makes it possible to obtain a contact that can be said to be “hermaphroditic”. The invention thus makes it possible to have a single component suitable for being used equally well as a male type contact and as a female type contact.

The longitudinal axis of the contact may be rectilinear. The longitudinal axis of the contact may optionally be an axis of symmetry of the contact.

The middle portion may be substantially U-shaped in a plane containing the longitudinal axis of the contact, the back of the U-shape being connected to the second end of the contact and each branch of the U-shape being connected to an arm of the first end. The middle portion may present elasticity enabling the branches of the U-shape to be moved apart or towards each other, thus enabling the arms that form the first end of the contact to be moved apart or towards each other.

Each arm or respectively each branch may include at least one portion extending along a rectilinear first longitudinal axis, which may coincide with the longitudinal axis of the contact in certain positions of the arms and of the branches. In a variant, each arm, or each branch, may extend entirely along the first longitudinal axis.

Below, the term “height of an arm” or “height of a branch” is used to designate the long dimension of the cross-section of an arm or of a branch in a plane perpendicular to its first longitudinal axis, and the term “thickness of an arm” or “thickness of a branch” is used to designate the short dimension of the cross-section of the arm or of the branch, in the same plane perpendicular to its first longitudinal axis.

The height of an arm or of a branch is measured between two side edges of the arm or of the branch, this height possibly being constant or else varying in optionally monotonic manner along the first longitudinal axis of the arm or of the branch.

Each arm may present the same height. Each branch may present the same height.

The thickness of an arm, or of a branch, may be constant or it may vary in optionally monotonic manner along the first longitudinal axis of the arm or of the branch.

The height of the branches may be greater than the height of the arms.

By way of example, an arm may be connected to the adjacent branch solely over a fraction of the height of the arm.

The arms may present the same thickness. The branches may present the same thickness. Both the arms and the branches may present the same thickness.

When the branches present the same height, the height may be equal to substantially twice the distance between the two branches as measured along the back of the middle portion.

In a plane perpendicular to the longitudinal axis of the contact, each arm may have at least one portion extending along a second longitudinal axis, said portions being such that the second longitudinal axes intersect.

When the first end has exactly two arms, the two second axes intersect.

The second longitudinal axes may be rectilinear or curvilinear. When the two longitudinal axes are rectilinear, the acute angle between them may for example lie in the range 0° to 45°.

Each arm is such that the two arms slope apart from each other on moving along the projection of an arm onto the plane perpendicular to the longitudinal axis of the contact. The projection of each arm onto said plane perpendicular to the longitudinal axis of the contact may present two ends, each of these ends facing an end of the projection of the other arm onto said plane, and the arms may be such that the size of the opening provided between the two facing ends is different from the size of the opening provided between the other two facing ends. Each of the above sizes may be the distance between the two facing ends when the contact is symmetrical, or between one of the facing ends and the other branch, when the contact is not symmetrical.

Each arm may be such that the first end of the contact presents a V-shape in cross-section in the plane perpendicular to the longitudinal axis of the contact. In such an example, the two arms slope apart from each other in continuous manner on moving along the projection of an arm onto said plane perpendicular to the longitudinal axis of the contact. Still in this example, the second longitudinal axes are rectilinear and the entire projection of each arm onto the plane perpendicular to the longitudinal axis of the contact extends along the second longitudinal axis.

In a variant, each arm is such that the first end of the contact presents a substantially U-shaped cross-section in the plane perpendicular to the longitudinal axis of the contact. In such an example, the arms slope apart from each other in continuous manner on moving along the projection of an arm onto said plane perpendicular to the longitudinal axis of the contact, after which they extend in parallel manner. Still in this example, the second longitudinal axes are curvilinear.

In another variant, each arm is such that the first end of the contact presents, in cross-section in the plane perpendicular to the longitudinal axis of the contact, a shape comprising in combination a V-shaped portion extended by a portion in which the two arms extend in parallel.

The contact may be such that when the first end is not subjected to any deformation force, the contact then being at rest, in particular when it is not connected to another contact, the two arms present at least one zone in which they are in contact with each other.

The middle portion of the contact may be made of cupro beryllium (CuBe₂), in particular by forming. A conductive coating, e.g. of gold, may be used. The use of such a material may serve to impart the above-mentioned elasticity properties to the middle portion of the contact.

The contact may be made as a single piece, which contact may be made integrally as explained above for the middle portion.

In a variant, the first end and/or the second end of the contact may be made of materials that are different from the material(s) of the middle portion.

Other exemplary embodiments of the invention also provide a connection system, including at least two contacts as defined above, the two arms of one of the contacts being held between the two arms of the other contact and bearing against them in such a manner as to ensure that the two contacts are connected together.

Thus, while using the same contacts, the invention makes it possible to establish a connection of the male/female type.

The contacts may convey any of the following signals:
a high-power signal;
an electrical power supply signal;
a radiofrequency signal, in particular a microwave signal; and
a digital signal.

When it is desired to establish a radiofrequency connection, in particular a microwave connection, three pairs of contacts may be used.

When it is desired to establish a digital connection, at least one pair of contacts is used, with another pair possibly forming a reference pair.

A single connection system may include several pairs of contacts connected together, at least one pair being dedicated to a given type of signal, for example three pairs for passing a radiofrequency signal, in particular a microwave signal, at least one pair for passing an electrical power supply signal, at least one pair for passing a high-power signal, and at least one pair for passing a digital signal, in combination with a reference pair.

Other exemplary embodiments of the invention provide a housing for an electronic card connector, the housing comprising:
at least one recess for receiving at least one electric contact; and
a coupling member for coupling with another housing, said coupling member comprising at least a first piece and at least a second piece, the first and second pieces being of complementary shapes.

By means of the coupling member, each housing may have a coupling piece of the male type and a coupling piece of the female type, and when the housing is connected to another housing that is identical, the male type coupling piece of each housing co-operates with the female type coupling piece of the other housing.

This serves to obtain a hermaphroditic housing.

By way of example, the coupling pieces may be portions in relief arranged in or on the housing. The coupling pieces may be fittings attached to the housing.

The coupling pieces may carry means for coding the housing, where such coding means enable a user to use the housing for applications that are adapted thereto.

For example, each housing may have only one first coupling piece and only one second coupling piece. Under such circumstances, the first coupling piece and the second coupling piece may be arranged at opposite ends of the housing.

Each coupling piece may extend along all or part of a face of the housing, e.g. along a rectilinear axis.

The housing may be made of plastics material(s). Such a housing may provide mechanical protection to the contact(s) received therein, and when a plurality of contacts are received, it may serve to provide electrical insulation between the contacts.

When the housing is connected to another housing, a metal cover may be arranged astride both housings, thereby providing electrical shielding for all or part of the two connected-together housings. In a variant, the electrical shielding may be obtained by metal-plating all or a portion of each housing. By way of example, the shielding may be provided over a microwave portion of the connectors.

Other exemplary embodiments of the invention also provide an electronic card connector comprising:
a housing; and
at least one contact as defined above, the contact being received in the housing and the first end of the contact preferably being arranged in an opening in the housing.

The connector may have at least three contacts passing a radiofrequency signal, in particular a microwave signal, and/or at least one contact passing a high-power signal, and/or at least one contact passing a digital signal in combination with a reference contact, and/or at least one contact passing a signal for electrical power supply. Such a connector may serve to carry electrical power supply and to pass communications signals between two electronic cards.

By way of example, and possibly in combination with other contacts, the connector may have three contacts conveying a microwave signal, thus facilitating coplanar microwave matching of the connection.

The housing may be as defined above, thus making it possible to obtain a hermaphroditic connector when all of the contacts and the housing are hermaphroditic.

The hermaphroditic housing may have uprights that separate distinct recesses arranged in such a manner that each recess between two adjacent uprights receives two contacts.

When two connectors with housings are connected together, adjacent contacts arranged in one housing are separated from each other by an upright of the housing passing said contacts all of the housing of the connector coupled thereto.

Other exemplary embodiments of the invention also provide a unit comprising:
a radiofrequency module including an electronic circuit card; and
a connector as defined above, the second end of the contact being mounted on the electronic card.

Other exemplary embodiments of the invention also provide a method of connecting together two units as defined above, wherein the two units are connected together by inserting the arms of a contact of one unit between the arms of a contact of the other unit in a first direction along a plugging axis that is not parallel to the longitudinal axis of one of said contacts.

The two units may be disconnected by applying a force to one of the units in the first direction along said plugging axis, said force leading to movement in the first direction along said axis of the unit that is disconnected.

The plugging axis may form a non-zero acute angle with the longitudinal axis of one of the contacts, e.g. an angle that is greater than 0° and less than or equal to 90°.

Because of the elastic properties of the middle portion of each contact and because of the overlap zone between the arms of two contacts when they are connected together, any misalignment or disalignment of the electronic cards to which the second ends of the contacts are connected may be compensated in any direction in order to pass the signal(s). Such misalignment may be less than or equal to 0.6 millimeters (mm) in any direction.

Once two radiofrequency modules have been connected together, the electronic cards of the units may remain in the same plane.

The direction and the order in which the operations of connecting and disconnecting two units are performed may be random and have no effect on the speed with which connection is established or the reliability thereof. That is to say a force may be applied on the first unit in order to connect it to the second unit and a force may be applied to the same first unit in order to disconnect it from the second unit or said disconnection force may be applied to the second unit. The force applied for connecting the two units together and the force applied for disconnecting them may be along the same axis and in the same direction, or along the same axis and in opposite directions, and the unit that its being disconnected may be subjected to movement along the same axis and in the same direction or in the opposite direction to the unit for connecting.

### BRIEF DESCRIPTION OF THE DRAWINGS

The invention can be better understood on reading the following description of a non-limiting embodiment thereof and on examining the accompanying drawings, in which:

FIG. 1 shows an example of two units in an embodiment of the invention;

FIG. 2 shows the contact of each unit in FIG. 1 in isolation;

FIG. 3 is a view of the contact looking along III of FIG. 2;

FIG. 4 is a view of the contact looking along IV of FIG. 3;

FIG. 5 is a view showing in isolation a contact in another embodiment of the invention;

FIGS. 6 to 10 show different steps while connecting together the contacts of FIGS. 2 to 5;

FIGS. 11 and 13 show embodiments of connectors of the invention;

FIG. 12 is a view showing the housing of the FIG. 13 connector in isolation;

FIGS. 14 to 16 show variants of FIG. 1; and

FIG. 17 shows two units with connectors of FIG. 13 when they are connected together.

### MORE DETAILED DESCRIPTION

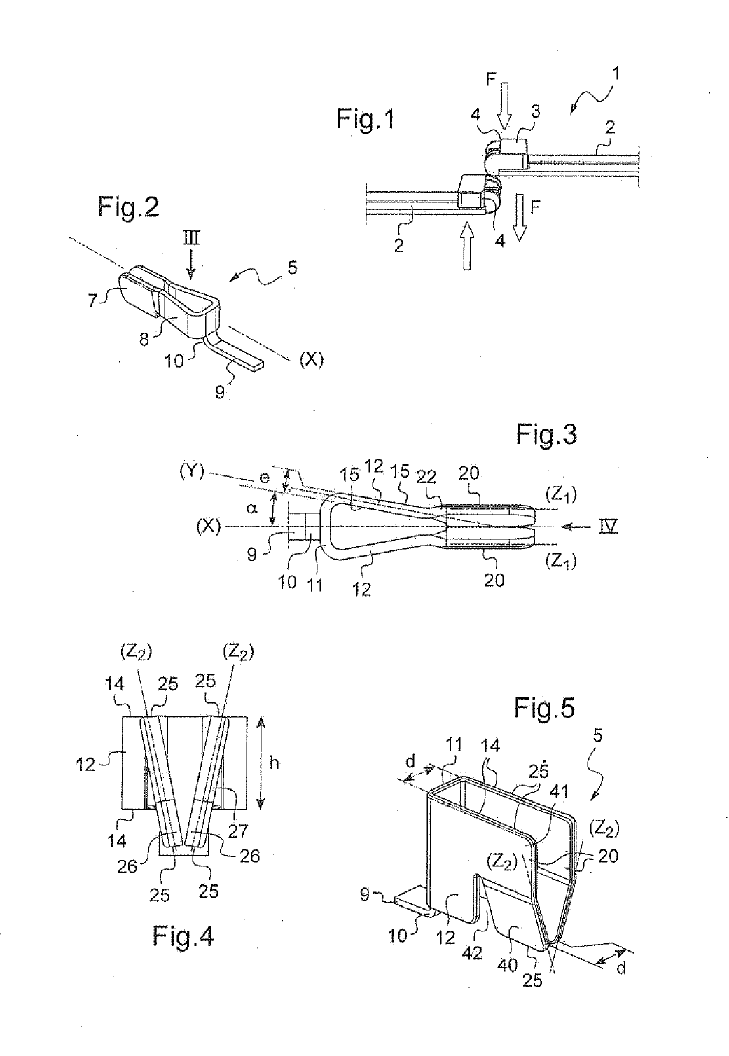

FIG. 1 shows an example of a unit given overall reference 1. The unit 1 comprises a radiofrequency module having an electronic card 2 with a connector 3 mounted thereon. The connector 3 comprises a housing 4 with one or more contacts given overall reference 5.

The connector 3 is configured to be connected to a connector of complementary type of another unit 1. A first example of a contact 5 is shown in greater detail in FIGS. 2 to 4.

The contact 5 in the example described is made as a single piece of cupro beryllium that has been “formed” (i.e. it has been cut out from a sheet and rolled). The contact 5 extends along a longitudinal axis X which in this example is rectilinear. Along this axis X, the contact 5 comprises in succession a first end 7, a middle portion 8, and a second end 9.

As can be seen in FIG. 1, the second end 9 of the contact 5 is mounted on the electronic card 2 when the contact 5 is placed in the housing 4 of the connector 3. The second end 9 may for example be in the form of a tab extending parallel to the axis X, with the exception of a curved portion 10 connected to the middle portion 8.

The middle portion 8 in the example described is substantially U-shaped when observed in a plane containing the longitudinal axis X of the contact. The middle portion 8 in the example of FIGS. 2 to 4 has a back 11 having connected thereto the second end 9 via the curved portion 10. The back 11 extends substantially perpendicularly to the longitudinal axis X of the contact 5.

The middle portion 8 also has two branches 12 that extend from the back 11 towards the first end 7 along a first longitudinal axis Y.

The material selected for making the contact, or only the middle portion 8, where appropriate, enables the angle a defined between the axis X and the contact 5 and the first longitudinal axis Y to vary. By way of example, the middle portion 8 is configured so that the angle a may vary over the range 0° to 30°.

Each branch 12 may present a thickness and/or a height that is substantially constant on going along the axis Y. The height h of each branch 12 is measured between two side edges 14 between which each branch 12 extends in a plane perpendicular to the first longitudinal axis Y.

Each branch 12 may present the same shape and, by way of example, the height h of each branch 12 may lie in the range 1 mm to 5 mm. The thickness of a branch 12, measured between two other edges 15 between which each branch 12 extends in a plane perpendicular to the first longitudinal axis Y may for example lie in the range 0.15 mm to 0.40 mm.

Each branch 12 has its end opposite from the back 11 connected to an arm 20, and the two arms 20 form the first end 7 of the contact 5. The junction between a branch 12 and arm 20 may be obtained using a portion 22 that makes an angle relative to the first longitudinal axis Y of each branch 12.

In the example of FIGS. 2 to 4, each arm 20 extends along a first longitudinal axis Z₁ from the portion 22 towards a rounded zone 27 forming the front face of the contact 5.

In a rest position of the contact 5, i.e. when the contact is not subjected to any force such as that exerted by a complementary contact, the first longitudinal axis Z₁ of an arm 20 may be parallel to the first longitudinal axis Z₁ of the other arm 20, and these two axes Z₁ may be parallel to the longitudinal axis X of the contact 5.

In addition, in this rest position on the contact 5, the two arms 20 may present at least one zone 26 in which they are in contact with each other.

As can be seen in FIG. 4, in a plane perpendicular to the axis x of the contact 5, the projection onto said plane of each arm 20 may extend completely or in part along a second longitudinal axis Z₂ between two edges 25, and the axis Z₂ of one arm 20 and the axis Z₂ of the other arm 20 intersect, so that the first end 7 presents a V-shape in section in said plane perpendicular to the axis X. From one side edge 25 to the other of each arm 20, the arms may spread apart from each other.

FIG. 5 shows a contact 5 in another embodiment of the invention.

Unlike the embodiment of FIGS. 3 and 4, the projection onto the plane perpendicular to the axis X of each arm 20 extends from an edge 25 only along a portion 40 along the second longitudinal axis Z₂, the first end 7 of the contact 5 in this portion 40 presenting a V-shape in section in said plane. Each portion 40 is extended to the other edge 25 by a portion 41 of the arm such that the arms 20 extend in parallel in these portions 41.

In the embodiment of FIG. 5, the arms 20 and the branches 12 are connected to each other only over a fraction of their height, a slot 42 being arranged over a fraction of the height of each branch 12. The portion 41 of the arm 20 extends in line with a portion of the branch 12, while the slot 42 is arranged all along the portion 40.

By way of example, the contact 5 shown in FIG. 5 presents the following dimensions: the height h of each branch 12 lies in the range 1 mm to 5 mm, the length of the back 11 measured between the two branches 12 lies in the range 1.5 mm to 3 mm, and the acute angle formed between the second longitudinal axes Z₂ lies in the range 0° to 45°.

In another embodiment that is not shown, each arm has a portion extending along a curvilinear second longitudinal axis, and the first end 7 presents a section in said plane perpendicular to the axis X that is substantially U-shaped.

In all of the embodiments described above, in which the contacts 5 are symmetrical, by way of non-limiting example, the distance d as measured between the edges 25 of the facing arms 20 differs from one end to the other of the projection of each of the arms 20 onto the plane perpendicular to the longitudinal axis X.

When the contact 5 is at rest, this distance d may be zero or very small between two of the facing edges 25 and it may be significantly greater between the other two facing edges 25, as can be seen in FIG. 5, for example.

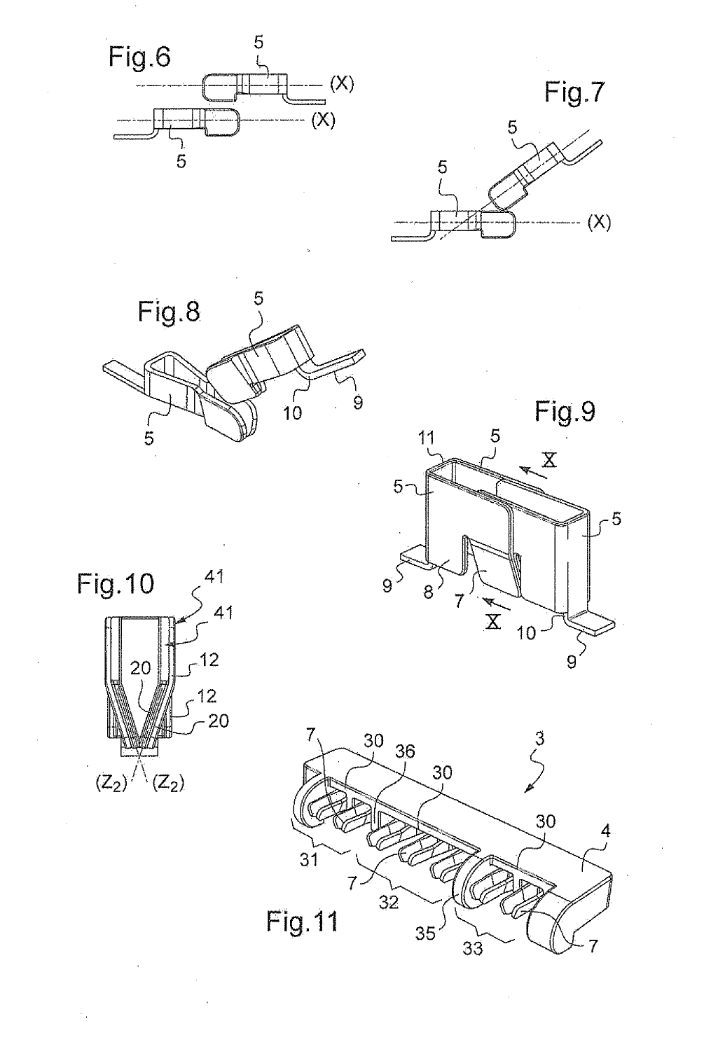

With reference to FIGS. 6 to 10, there follows a description of examples of how the contact 5 can be used. The contacts may be used equally well for conveying a radiofrequency signal, in particular a microwave signal, or a digital signal, or a power supply signal, or a high-power signal.

As can be seen in FIG. 6, the contact described with reference to FIGS. 2 to 4 or with reference to FIG. 5 may be used to make a connection system by using two identical contacts 5, one acting as a female type contact and the other acting as a male type contact. The connection of one contact 5 with another is made by inserting the two arms 20 of one of the contacts between the arms 20 of the other contact, it being possible to insert said arms 20 because of the elasticity of the middle portions 8 and/or of the arms 20 themselves, and also because of the considerable spacing between them. It is thus possible to space the two arms 20 of a contact 5 far enough apart from each other to enable the two arms 20 of the other contact 5 to be received between these two arms and to press against them.

In FIG. 6, the two contacts 5 are connected along a plugging axis perpendicular to the longitudinal axis X of each of the contacts, whereas in the example of FIGS. 7 and 8, the plugging axis is parallel to the longitudinal axis X of one of the contacts and forms a non-zero acute angle with the longitudinal axis of the other contact.

FIGS. 9 and 10 show the contacts 5 of FIG. 5 in the connected state.

As shown in FIG. 11, the connector 3 may comprise a plurality of contacts 5, these contacts being received in the housing 4. Each contact 5 may be arranged in a recess 29 in the housing 4, such that the first end 7 of each contact 5 is positioned in an opening 30 formed in the housing 4 and communicates with the recess 29.

In the embodiment of FIG. 11, the connector 3 has a plurality of contacts dedicated to passing signals of different types. A first group 31 of contacts 5 serves for example to convey a high-power signal, while a second group 32 of contacts 5 serves to convey a radiofrequency signal, in particular a microwave signal, and a third group 33 of contacts 5 serves to convey a digital signal.

In the embodiment of FIG. 11, three different groups are provided, and the groups 31 and 33 have two contacts 5 each, while the group 32 has three contacts, but the invention is not limited to a connector with any predefined number of groups, and within the groups conveying a digital signal, a high-power signal, or a power supply signal, it is not limited to any predefined number of contacts 5.

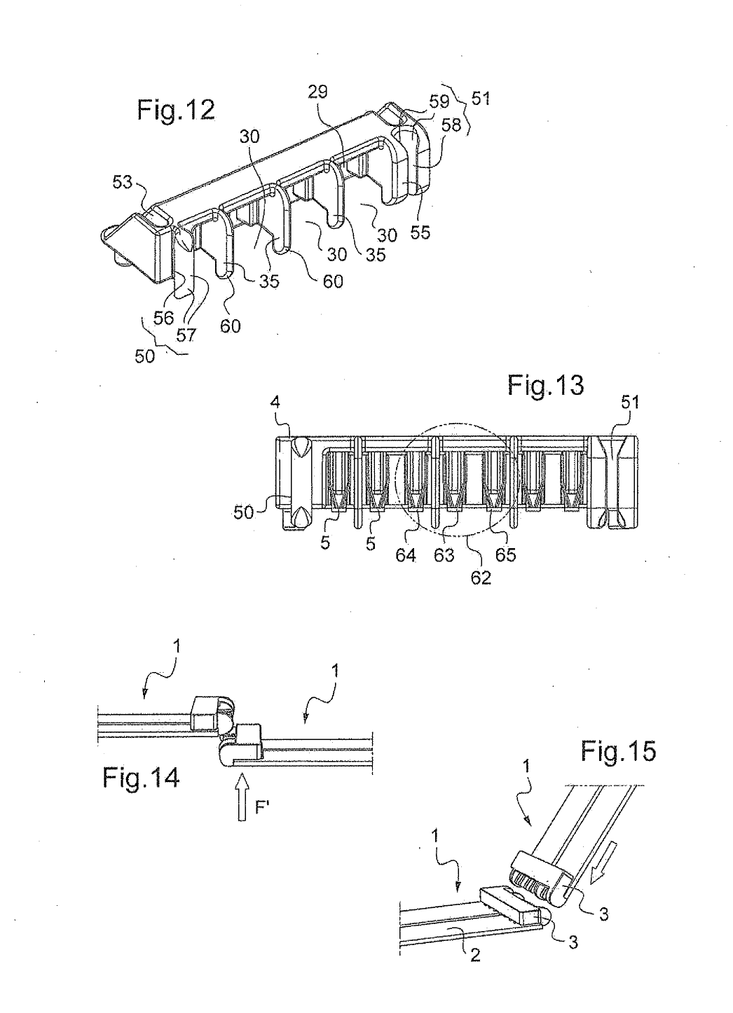

Two adjacent openings 30 may be separated by uprights 35 and 36 of the housing 4. In the embodiment of FIG. 11, the uprights 35 and 36 are of different shapes, the upright 35 extending beyond the first ends 7 of the contacts 5 when the contacts are in place in the housing 4, whereas an upright 36 is set back from the first ends 7 of the contacts 5. When two units 1 including connectors of the kind shown in FIG. 11 are connected together, the uprights 36 of the first housing co-operate with the uprights 35 of the housing of the other connector. In the embodiment of FIG. 12, the uprights 35 co-operate with the openings 30 of the housing 4 of the other connector 3, and each contact 5 of the connector 3 is separated by an insulating upright 35 from the adjacent contacts, the upright 35 belonging to one or the other of the housings 4.

In the embodiment of FIG. 11, the housing 4 does not have a member for coupling to the housing of the other connector 3.

The invention is not limited to such an embodiment, as can be seen in FIGS. 12 and 13.

In these figure, the housing 4 is provided at two opposite ends with coupling pieces 50 and 51. A first coupling piece 50 of the male type is arranged at one end of the housing while a second coupling piece 51 of the female type is arranged at the other end of the housing. These coupling pieces 50 and 51 in this embodiment are of complementary shapes, such that if they were not secured to the housing 4 they could be coupled together.

As shown in FIG. 12, at each end of the housing 4, the corresponding coupling piece 50 or 51 is in register in the housing 4 with a cavity 53.

The first coupling piece 50 projects locally from the housing 4 and it may extend all along the face 55 of the housing that faces another housing 4 when the two housings 4 are connected together. The first coupling piece 51 may present a connection zone 56 with the housing 4 that is extended by faces 57 that diverge and then converge on going away from the housing 4.

In the embodiment of FIG. 12, the second coupling piece 51 is in the form of a slot presenting a zone 58 that opens to the outside and that is suitable for receiving the connection zone 56, the zone 58 being extended towards the inside of the slot by a zone having faces 59 of a shape complementary to the shape of the faces 57 of the first coupling piece 50.

Two openings 30 in the housing 4 of FIG. 12 are separated by uprights 35 presenting forward extensions 60 for protecting the contacts 5 while the connector is being handled.

FIG. 13 is a face view of the housing of FIG. 12 with contacts 5 mounted therein. Four groups of contacts 5 are received in the housing 4. In the embodiment described, the arrangement of the contacts 5 provides a microwave portion 62 made up of a central contact 63 and contacts 64 and 65 forming ground distributed on either side. The microwave portion 62 thus has three contacts 63, 64, and 65 conveying a microwave signal.

As can be seen in FIG. 1, in the invention a unit 1 may be connected to another unit 1 along a plugging axis that is perpendicular to the longitudinal axis of each contact and to the plane in which the electronic card 2 of each unit extends.

A unit 1 may be disconnected from the other by applying a force F to one of the units 1 that is directed along the same plugging axis and direction, so that the unit 1 is moved along the same axis and in the same direction both when it is connected to another unit 1 and when it is disconnected therefrom.

Compared with the embodiment of FIG. 1, the embodiment of FIG. 14 shows that the two units 1 may be connected and disconnected by applying a force F along the same plugging axis of FIG. 1, but in the opposite direction.

As can be seen in FIG. 15, the invention is not limited to connecting units 1 having electronic cards 2 that have previously been arranged parallel to each other. Connection may be obtained by applying a force along a plugging axis that makes a non-zero acute angle that is not equal to 90° with the longitudinal axis of at least one contact 5 for connection. During the connection operation, the electronic cards of the two units for connecting together may extend in planes that are not parallel and the plugging axis may be at an angle that is greater than 0° and less than 90°, in particular that is about 45°, relative to the plane in which one of the electronic cards 2 extends.

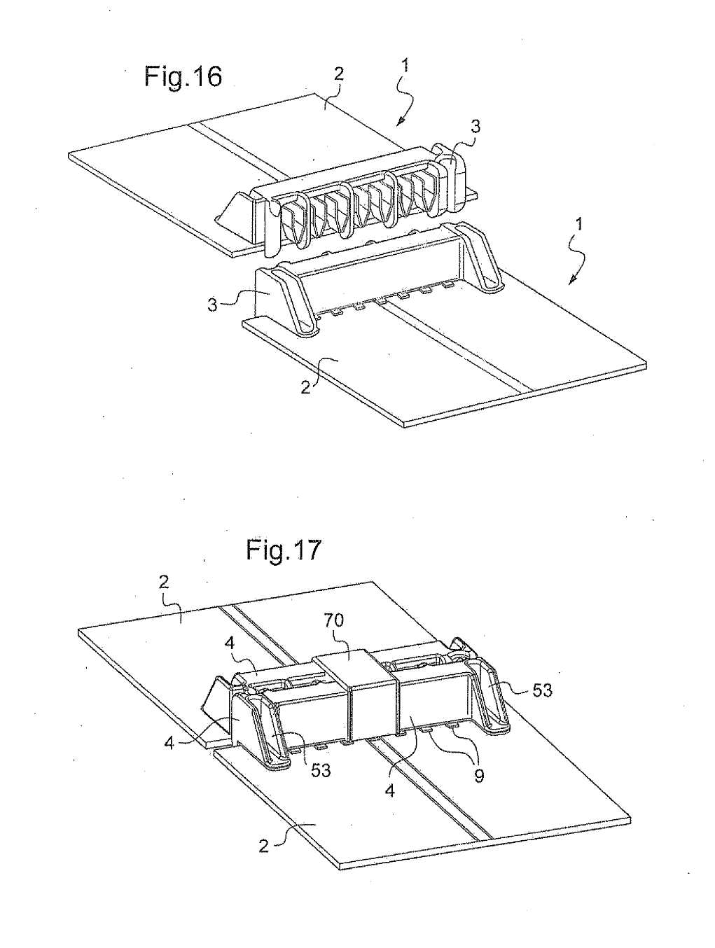

In the embodiment of FIGS. 16 and 17, the connector 3 has contacts 5 as shown in FIG. 5 and a housing 4 as shown in FIGS. 12 and 13.

When two connectors 3 are connected together, as shown in FIG. 17, a shielding metal cover 70 may be mounted astride the housings 4, e.g. over their central portion. The cover 70 may be installed in particular to cover the microwave portion 62, when such a portion exists. In a variant, the shielding may be obtained by metal-plating the housing 4, at least in its microwave portion 62, when the housing is made of plastics material(s).

What is claimed is:

1. An electric contact for a connector, the contact comprising:
a first end for connecting to another contact; and
a second end opposite from the first end along a longitudinal axis of the contact;
wherein:
the contact includes at least two distinct arms forming the first end and a middle portion arranged between the first and second ends and configured to enable said arms to move apart and/or towards each other, and
each arm is such that the two arms slope apart from each other on moving along a projection of an arm onto a plane perpendicular to the longitudinal axis of the contact.

2. The contact according to claim 1, the middle portion being substantially U-shaped in a plane containing the longitudinal axis of the contact, a back of the U-shape being connected to the second end and each branch of the U-shape being connected to an arm of the first end.

3. The contact according to claim 1, each arm and/or each branch including at least one portion extending along a rectilinear first longitudinal axis, which may coincide with the longitudinal axis of the contact in certain positions of the arms and of the branches.

4. The contact according to claim 1, each arm having at least one portion extending along a second longitudinal axis in a plane perpendicular to the longitudinal axis of the contact, said portions being such that the second longitudinal axes intersect.

5. The contact according to claim 4, the second longitudinal axes being rectilinear or curvilinear.

6. The contact according to claim 1, each arm being such that the first end of the contact presents a V-shape in cross-section in the plane perpendicular to the longitudinal axis of the contact.

7. The contact according to claim 1, each arm being such that the first end of the contact presents a substantially U-shaped cross-section in the plane perpendicular to the longitudinal axis of the contact.

8. The contact according to claim 1, each arm being such that the first end of the contact presents, in cross-section in the plane perpendicular to the longitudinal axis of the contact, a shape comprising in combination a V-shaped portion extended by a portion in which the arms are parallel.

9. A connection system, including at least two contacts according to claim 1, the two arms of one of the contacts being arranged between the two arms of the other contact and coming to bear thereagainst in such a manner as to ensure connection between the two contacts.

10. The connection system according to claim 9, the contacts conveying one of the following signals: a high-power signal, a radiofrequency signal, an electrical power supply signal, and a digital signal.

11. A housing for an electronic card connector, the housing comprising:
at least one recess for receiving at least one electric contact according to claim 1; and
a coupling member for coupling with another housing, said coupling member comprising at least a first piece and at least a second piece, the first and second pieces being of complementary shapes.

12. An electronic card connector comprising:
a housing according to claim 11; and
at least one contact received in the housing, the at least one contact comprising:
a first end for connecting to another contact; and
a second end opposite from the first end along a longitudinal axis of the contact;
wherein:
the contact includes at least two distinct arms forming the first end and a middle portion arranged between the first and second ends and configured to enable said arms to move apart and/or towards each other, and
each arm is such that the two arms slope apart from each other on moving along a projection of an arm onto a plane perpendicular to the longitudinal axis of the contact.

13. The connector according to claim 12, including at least three contacts conveying a radiofrequency signal, and/or at least one contact conveying a high-power signal and/or at least one contact conveying a digital signal combined with a reference contact and/or at least one contact for electrical power supply.

14. A method of connecting together two units, each unit comprising:
a radiofrequency module including an electronic card; and
a connector according to claim 12;
the second end of the contact being mounted on the electronic card, the method comprising:
inserting the arms of a contact of one unit between the arms of a contact of the other unit in a first direction along a plugging axis that is not parallel to the longitudinal axis of one of said contacts, thereby connecting together the two units.

15. The method according to claim 14, wherein the two units are disconnected by applying a force to one of the units in the first direction along said plugging axis, said force leading to movement in the first direction along said axis of the unit that is disconnected.

16. The connection system according to claim 10, wherein the radiofrequency signal is a microwave signal.

17. The connector according to claim 13, wherein the radiofrequency signal is a microwave signal.
